(19) United States
(12) Patent Application Publication
(10) Pub. No.: US 2005/0281003 A1
(43) Pub. Date: Dec. 22, 2005

(54) Waveguide power supply enclosure

(76) Inventors: Thomas J. Carullo, Marlton, NJ (US); Arthur G. Willers, Delran, NJ (US)

Correspondence Address: BECK AND TYSVER P.L.L.C., 2900 THOMAS AVENUE SOUTH, SUITE 100, MINNEAPOLIS, MN, 55416, US

(21) Appl. No.: 10/873,376

(22) Filed: Jun. 21, 2004

(51) Int. Cl. H05K 5/00

(52) U.S. Cl. 361/724

(57) ABSTRACT

A power supply enclosure device and method for suppressing the radiation of EMI from a power supply along power lines and for suppressing the entry of RF EMI into the power supply through the use of multiple tuned waveguides.

The present invention relates generally to electromagnetic interference shielding of electronic equipment and in particular to a power supply enclosure to suppress radiation from the power supply.

### BACKGROUND OF THE INVENTION

The use of electromagnetic interference (EMI) shielding enclosures to suppress the radiation of electromagnetic energy is widely known. The typical EMI suppression enclosure will include a closed box-like structure made from a non-porous electrically conductive material such as steel. The conductive enclosure forms a Faraday cage to prevent the entry or exit of EMI. Although a closed box is ideal, real world enclosures require apertures and other openings and appendages to admit cooling air to cool electronic componetry inside the enclosure, and to permit the passage of signals and power in and out of the device.

It is important that cables entering the enclosure do not introduce EMI or radiate internally generated radio frequencies to the environment though the cables.

### SUMMARY OF THE INVENTION

In contrast to prior art structures and constructions, the power supply of the present invention includes a collection of nested enclosures which are configured to admit electrical power into the main enclosure while suppressing EMI or allowing EMI to pass through the enclosure from near by sources. The configuration prevents both the re-radiation of radio frequency (RF) energy created inside of the enclosure and suppresses the introduction of RF energy into the enclosure from the power line or from other sources related to the purpose of the Power Supply.

### BRIEF DESCRIPTION OF THE DRAWINGS

Throughout the several figures identical reference numerals indicated identical structure wherein:

FIG. 1 is a perspective view of a complete power supply assembly;

FIG. 2 is a perspective view of a power supply inserted into a chassis;

FIG. 2A is a phantom perspective view showing the power supply and its would relationship with a typical chassis application;

FIG. 2B is a phantom perspective view showing the power supply and subassemblies; and,

FIG. 2C is a phantom perspective view showing the power supply's AC (alternating current) inlet filter enclosure.

### DETAIL DESCRIPTION

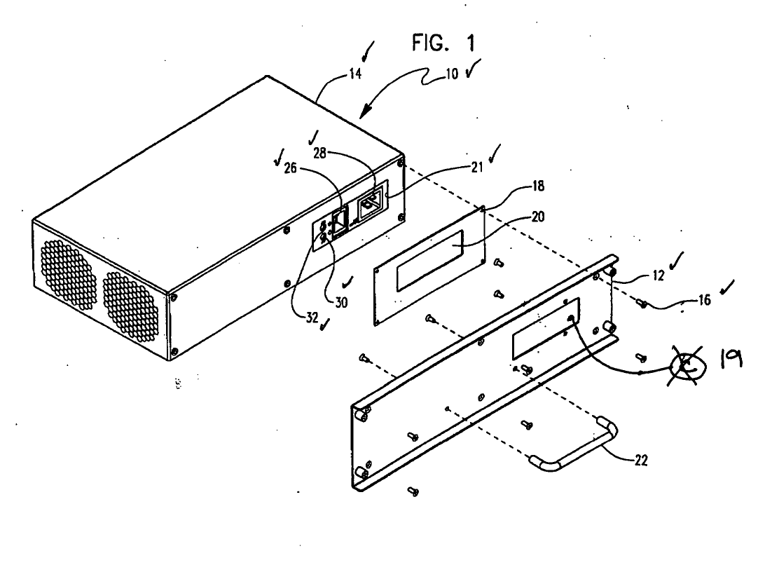

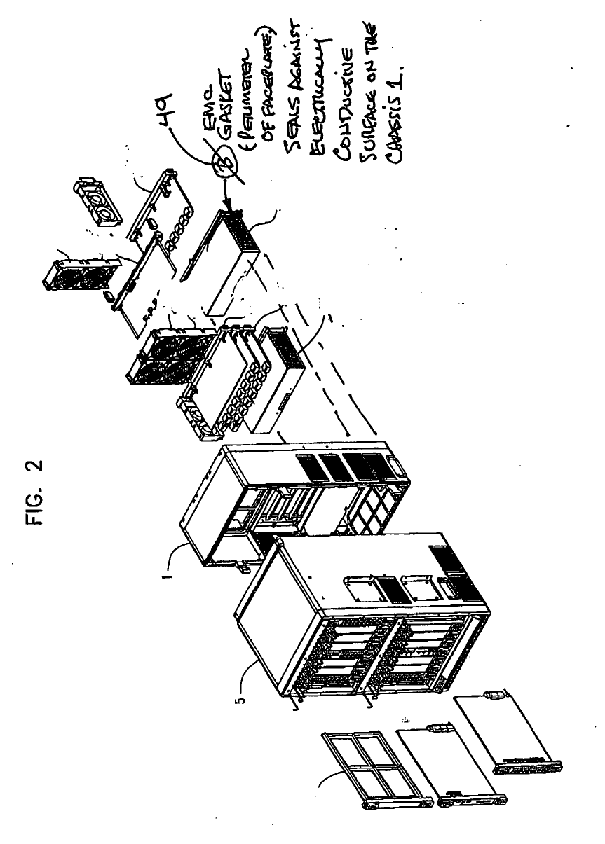

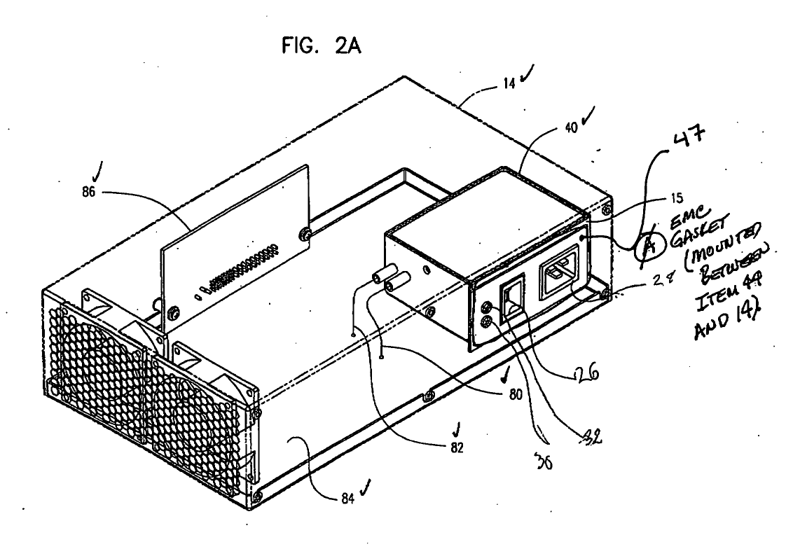

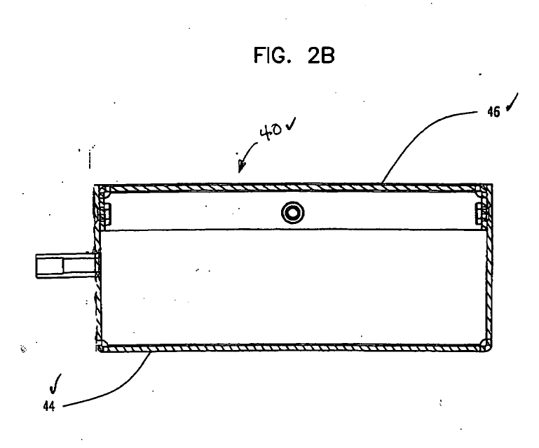

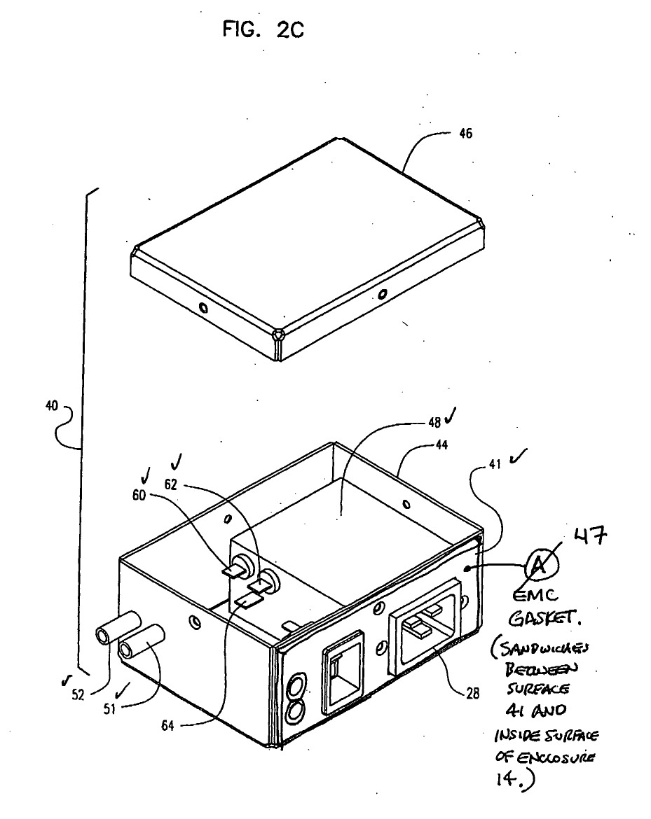

FIG. 1 shows the power supply 10 along with a faceplate 12 that is coupled to the primary chassis 14 with a set of screws typified by screw 16. The EMC (electromagnetic compliant) gasket 18 serves to electrically connect and to prevent any gap between the panel 12 and the primary enclosures 14. This gasket suppresses EMI (electromagnet interference) that may be radiated through apertures 20, 21 and 19, when the sum of the parts are connected and assembled. In addition, a perimeter gasket 49 is employed about the outer surfaces of the front faceplate to electrically seal the power supply assembly 32 to a electrically conductive surface on chassis frame 1 as seen in FIG. 2. The apertures 20, 21, and 19 frame a power switch 26, a three-prong power plug 28 and a pair of LED status indicators 30 and 32.

The handle 22 is attached to the faceplate 12 and it is used to grasp and plug and unplug the power supply into the larger enclosure of a telecommunication device such as a switch. This larger enclosure 1 electrically accepts the power supply enclosure 32.

The problem addressed by this construction is twofold. First any EMI present on the power supply cable attached to the plug 28 must not be allowed to enter the telecommunication equipment. Secondly, EMI originating within the power supply or entering the power supply from the telecommunication equipment must be suppressed. In this regard the apertures 20, 21, and 19 and the components located within the aperture are particularly troublesome.

FIG. 2A shows the internal packaging that suppresses the radiation of radio frequency energy. Secondary subassembly enclosure 40 seen in FIG. 2B is a three sided enclosure that allows components to be arranged internally, top cover 46 is positioned over enclosure 44 and forms a EMI seal with the addition of sealing compound or metallic tape to prevent leakage from the interface between 44 and 46, likewise a similar cover application makes up enclosure 14. Enclosure 40 is then positioned within the primary power supply enclosure 14 and these two enclosures or housings mate in a lap joint along one common wall. In this fashion they essentially share a wall that is sealed by a conductive gasket 47. For example wall 15 (inside surface) of the enclosure 14 overlaps wall 41 of enclosure 40 with the inclusion of gasket 47. This construction prevents energy from leaking around enclosure 40 and out apertures 20, 21, and 19.

With respect to FIG. 2C, within subassembly enclosure 40 there is a filter enclosure 48 around the power plug 28. In general the plug 28 could be a 220 two-phase male plug with two “hot” conductors and a common neutral conductor. In FIG. 2C two feed-through 60 and 62 are used to carry the hot conductors to the interior of the subassembly secondary enclosure 40. These feed-through connectors operate as bypass capacitors and RF energy on either conductor is readily shunted to the ground potential of the surrounding metallic enclosure.

Power conductors 80 and 82 exit the enclosure 40 though waveguide tubes 51 and 52. Power Conductors 80 and 82 terminate on the PCB board 84. These conductors are insulated from the tubular waveguide connectors 52 and 51. The waveguide tubes have length and diameter sufficient to suppress and attenuate RF in the megahertz and gigahertz ranges.

The conductors 80 and 82 supply AC power to the populated power supply printed circuit board 84. Though not seen in the figure this board 84 will be populated with the normal and conventional power supply components including bridge rectifiers, voltage transformers, filtering capacitors and the like. The DC power developed on the board 84 is required for other electronic equipment not shown. The DC power is routed off the board and through the primary enclosure through a connector 86. It is important to note that the primary enclosure is required primarily for voltage safety and mechanical robustness and it is relatively “leaky” from an EMI standpoint. The RF suppression occurs primarily in the secondary enclosure 40 and the filter enclosure 48. The shared wall and sealing gaskets 47 and 18 complete the containment attributes.

Thus, in this fashion electrical interference is suppressed and routed to ground as it is introduced into the primary enclosure 14 preventing it from being radiated out of the power line connectors housed in enclosure 40. In a similar fashion RF signals on the power supply line are suppressed and prevented from being introduced into the primary enclosure 14 through the same attenuating connectors.

Applicants have found that this architecture of multiple suppression enclosures produces a “clean” power supply that prevents leakage of RF energy both into and out, and passing through the primary enclosure.

1. A power supply enclosure comprising:
a primary enclosure having a gasketed panel wall defining an aperture;
a secondary enclosure mounted within said primary enclosure and coupled to said gasketed panel wall aligned with said aperture;
said secondary enclosure having one or more waveguide tubes positioned on a wall of said secondary enclosure;
a filter positioned within said secondary enclosure that removes signal noise passing between the power supply and an external power source;
a power plug located within said filter enclosure
said power plug having at least one conductor, entering said secondary enclosure through a bypass capacitor;
said power plug lies within said aperture whereby power cabling may attach to said plug proximate said aperture and said secondary enclosure defining essentially a Faraday cage.

2. A system to prevent EMI and RFI radiation from passing through a power supply located with a chassis box, comprising:
a. a power supply enclosure within the chassis box containing the power supply and sharing a common portion of a exterior wall with the chassis box, all walls of said power supply enclosure being formed from an electrically conductive material that prevents electromagnetic emissions from passing therethrough;
b. a main compartment, consisting of the volume within the chassis box that is outside the power supply enclosure;
c. a plurality of electronic components located within the main compartment;
d. one or more waveguide tubes connecting the interior of the power supply enclosure, each waveguide having a wire passing through each of said tubes carrying power to the electronic components from the power supply, the inside dimensions and lengths of said waveguide tubes selected to attenuate the range of frequencies radiated by the electronic components;
e. a power plug, located in an aperture in the common portion of the exterior wall, said power plug connected by a wire to an external power source; and
f. a filter, located within the power supply enclosure, that removes EMI and RFI frequencies from electricity passing through a connection between the power plug and the power supply, through which connection the power supply receives power from the external source,
wherein said walls of the power supply enclosure, said filter, and said waveguide tubes combine to defining essentially a Faraday cage in the power supply enclosure.

3. The system of claim 2, wherein the walls of the main compartment are formed from material preventing electromagnetic radiation from passing therethrough, defining essentially a Faraday cage in the main compartment.
